(19) United States
(12) Patent Application Publication
(10) Pub. No.: US 2025/0133836 A1
(43) Pub. Date: Apr. 24, 2025

(54) METHOD FOR FILLING REDUNDANT METALS IN CHIP, CHIP AND SEMICONDUCTOR DEVICE

(71) Applicant: SUZHOU METABRAIN INTELLIGENT TECHNOLOGY CO., LTD., Suzhou, Jiangsu (CN)

(72) Inventors: E HOU, Suzhou, Jiangsu (CN); Jinchao QIU, Suzhou, Jiangsu (CN); Yunpeng WANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/574,667

(22) PCT Filed: Sep. 29, 2022
(86) PCT No.: PCT/CN2022/122739

§ 371 Date: Dec. 27, 2023

(30) Foreign Application Priority Data
Feb. 22, 2022 (CN) 202210159445.9

(51) Int. Cl. H10D 89/10; H10D 1/00; H10D 86/01; H10D 86/80

(52) U.S. Cl. CPC H10D 89/10; H10D 1/045; H10D 86/01; H10D 86/80

(57) ABSTRACT

The present application discloses a method for increasing capacitors in a chip, including: determining a capacitance value needing to be increased in a chip; according to the capacitance value, determining a length value of redundant metals required by a metal layer in the chip; and inserting the redundant metals having a total length of the length value into a preset region of the metal layer, and connecting the redundant metals to a power source and a grounding power source, wherein the redundant metals connected to the power source and the redundant metals connected to the grounding power source are arranged in an interdigital form.

### CROSS-REFERENCE TO RELATED APPLICATIONS

The present application is a National Stage Application of PCT International Application No.: PCT/CN2022/122739 filed on Sep. 29, 2022, which claims priority to Chinese Patent Application 202210159445.9, filed in the China National Intellectual Property Administration on Feb. 22, 2022, the disclosure of which is incorporated herein by reference in its entirety.

### TECHNICAL FIELD

The present application relates to the field of semiconductors, and in particular, to a method for filling redundant metals in a chip, a chip and a semiconductor device.

### BACKGROUND

A chip is provided with electronic components such as various transistors, resistors, capacitors and inductors, as well as wires for interconnecting these electronic components, the electronic components may work stably only when obtaining sufficient and stable power sources, and the power sources of the electronic components all come from a power grid. Due to the existence of resistance in the wires and through holes, when the current flows through the wires and the through holes from the power sources, a voltage reduction phenomenon is generated, such that the voltages of the electronic elements are lower than the voltages of the power sources. The more the wires and the through holes through which the current flows, the lower the voltages are, which affects the work of the electronic components, and thus affecting the performance and the use time of the chip.

In order to ensure the working stability of the electronic components on the chip, the capacitors of the chip may be increased, and the voltage of the chip may be stabilized. There are two ways to increase the capacitors of the chip at present, one is to use a PIP (poly-insulator-poly) capacitor structure, and the other one is to use an MIM (metal-insulator-metal) capacitor structure. At present, both the two capacitor structures need to additionally add photomasks, on one hand, the cost of the photomasks is high, such that the manufacturing cost of the chip is increased, and the the process of the chip is more tedious, and on the other hand, a large amount of winding resources are occupied to increase the area of the chip; and meanwhile, the number of capacitors increased in the two modes is limited. In addition, at present, when the voltage of the chip is stabilized, the power supply capability of the chip is usually enhanced by adding a power grid.

Therefore, how to solve the above technical problems should be focused by those skilled in the art.

### SUMMARY

An embodiment of the present application provides a method for increasing capacitors in a chip, including:
a capacitance value needing to be increased in the chip is determined;
according to the capacitance value, a length value of redundant metals required by a metal layer in the chip is determined; and
the redundant metals having a total length of the length value are inserted into a preset region of the metal layer, and are connected to a power source and a grounding power source, wherein the redundant metals connected to the power source and the redundant metals connected to the grounding power source are arranged in an interdigital form.

In one or more embodiments, when there are a plurality of metal layers into which the redundant metals may be inserted, the redundant metals are inserted into the metal layer at a topmost layer of the plurality of metal layers.

In one or more embodiments, when there are a plurality of metal layers into which the redundant metals may be inserted, the redundant metals are inserted into the plurality of metal layers, and the redundant metals are sequentially inserted into the metal layers downwards from the metal layer at a topmost layer of the plurality of metal layers.

In one or more embodiments, when there are a plurality of metal layers into which the redundant metals may be inserted, the metal layer into which the redundant metals are inserted is a layer with a minimum density of metal wires.

In one or more embodiments, the step of determining the capacitance value needing to be increased in the chip includes:
the capacitance value is determined according to a width value, a spacing and a thickness value of the metal layer, as well as a dielectric constant of a dielectric layer in the chip.

In one or more embodiments, the step: according to the capacitance value, determining the length value of redundant metals required by the metal layer in the chip, includes:
a relative area of adjacent redundant metals is determined according to a preset formula, wherein the preset formula is:

$$C = \frac{{ε}_{r} S}{4 π kd}$$

in the formula, C denotes the capacitance value, εᵣ denotes a relative dielectric constant, d denotes a distance between the adjacent redundant metals, k denotes a static power constant, and S denotes the relative area of the adjacent redundant metals; and
the length value is determined according to the relative area and a thickness of the redundant metals.

In one or more embodiments, the determination process of the preset region includes:
an initial density of metal wires in each grid region in a layout corresponding to the chip is determined;
it is judged whether the initial density is lower than a preset lowest density threshold value; and
if the initial density is lower than the preset lowest density threshold value, it is determined that the grid region corresponding to the initial density is the preset region.

In one or more embodiments, when the initial density is not lower than the preset lowest density threshold value and is lower than a preset highest density threshold value, the method includes:
a density difference between the grid region and an adjacent grid region is determined;
it is judged whether the density difference exceeds a preset difference threshold value; and
if the density difference exceeds the preset difference threshold value, it is determined that the grid region is the preset region.

In one or more embodiments, after the step of inserting the redundant metals having the total length of the length value into the preset region of the metal layer, and connecting the redundant metals to the power source and the grounding power source, the method further includes:
a density of the grid region is determined after the redundant metals are inserted, the density is used as a new initial density, and the step of judging whether the initial density is lower than the preset lowest density threshold value is executed, until the density difference between the each grid region and the adjacent grid region does not exceed the preset difference threshold value.

The present application further provides a chip, wherein redundant metals on the chip are connected to a power source and a grounding power source according to any method for increasing the capacitors in the chip as described above, and are arranged in an interdigital form.

In one or more embodiments, a substrate material of the chip is a composite material of silicon dioxide and aluminum nitride, or a composite material of silicon dioxide and silicon nitride, or silicon dioxide doped with high-valence cations.

The present application further provides a semiconductor device, wherein the semiconductor device includes any chip as described above.

The method for increasing the capacitors in the chip provided in the present application includes: determining a capacitance value needing to be increased in the chip; according to the capacitance value, determining a length value of redundant metals required by a metal layer in the chip; and inserting the redundant metals having a total length of the length value into a preset region of the metal layer, and connecting the redundant metals to a power source and a grounding power source, wherein the redundant metals connected to the power source and the redundant metals connected to the grounding power source are arranged in an interdigital form.

### BRIEF DESCRIPTION OF THE DRAWINGS

To illustrate technical solutions in the embodiments of the present application or in the prior art more clearly, a brief introduction on the drawings which are needed in the description of the embodiments or the prior art is given below. Apparently, the drawings in the description below are merely some of the embodiments of the present application, based on which other drawings may be obtained by those ordinary skilled in the art without any creative effort.

FIG. 1 is a flowchart of a method for increasing capacitors in a chip provided in an embodiment of the present application;

FIG. 2 is a schematic structural diagram of redundant metals connected to a power source and a grounding power source provided in an embodiment of the present application; and

FIG. 3 is a flowchart of determining a preset region provided in an embodiment of the present application.

### DETAILED DESCRIPTION OF THE EMBODIMENTS

In order to enable those skilled in the art to better understand the solutions of the present application, the present application is further described in detail below in combination with the drawings and specific embodiments. Apparently, the embodiments described below are merely a part, but not all, of the embodiments of the present application. All of other embodiments, obtained by those ordinary skilled in the art based on the embodiments in the present application without any creative effort, fall into the protection scope of the present application.

Numerous specific details are set forth in the following description to facilitate a thorough understanding of the present application, but the present application may also be practiced otherwise than as described herein, and those skilled in the art may perform similar promotion without departing from the connotation of the present application, therefore the present application is not limited by the specific embodiments disclosed below.

As described in the background art, when the capacitors of a chip are increased currently, a photomask needs to be additionally added for disposing a PIP capacitor structure or an MIM capacitor structure, on one hand, the cost of the photomask is high, such that the manufacturing cost of the chip is increased, and the the process of the chip is more tedious, and on the other hand, a large amount of winding resources are occupied to increase the area of the chip; and meanwhile, the number of capacitors increased in the two modes is limited. The power supply capability of the chip is enhanced by adding a power grid.

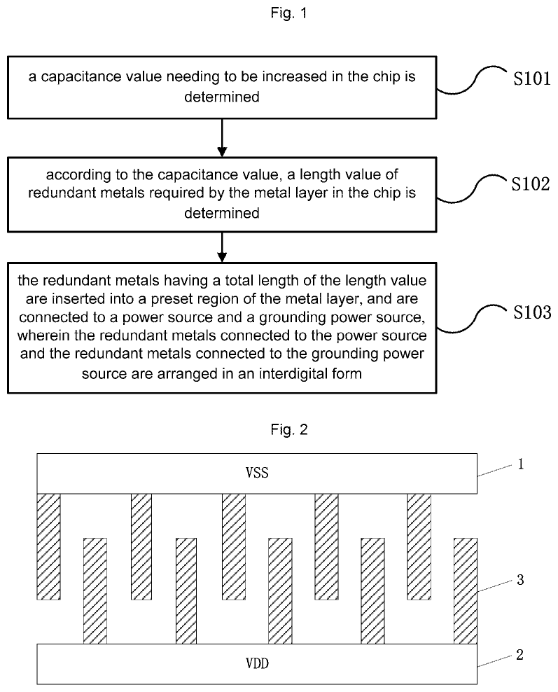

In view of this, the present application provides a method for increasing capacitors in a chip, and referring to FIG. 1, the method includes:

Step S101: a capacitance value needing to be increased in the chip is determined.

In the present step, the preset region is a region in which redundant metals need to be filled on a metal layer to balance the metal density.

In order to reduce an RC delay, the chip uses a three-dimensional and multi-layer wiring structure, and in order to meet the requirements of the three-dimensional and multi-layer structure and nanoscale feature sizes on material surface planarization, global planarization needs to be realized by using a chemical mechanical polishing (CMP for short) technology. In the CMP process, the non-uniform metal density results in fluctuation of the thickness of the metal, leading to a disc shape and wear, therefore redundant metals need to be filled to adjust the metal density, so that the metal density is consistent, thereby improving the flatness of the metal surface.

The redundant metal is a metal that does not play any conduction effect, and the redundant metal specially changes the pattern distribution of a layout by adding additional graphics units on the layout, so as to achieve the purpose of reducing the process deviation and improving the yield of the chip. That is, at present, in order to balance the metal density in each region on the metal layer of the chip, the redundant metal is filled, when the redundant metal is filled, a floating filling mode is utilized, and the floating filling refers to that the redundant metal is not connected to a power grid. Although the floating filling of the redundant metal may improve the metal density, the coupling capacitance and the ground capacitance are increased at the same time, which has a certain influence on a time sequence in the chip.

The step of determining the capacitance value needing to be increased in the chip includes:
the capacitance value is determined according to a width value, a spacing and a thickness value of the metal layer, as well as a dielectric constant of a dielectric layer in the chip. The specific determination process may refer to related arts, and thus details are not described in detail in the present application.

Step S102: according to the capacitance value, a length value of redundant metals required by the metal layer in the chip is determined.

In one or more embodiments, the step: according to the capacitance value, determining the length value of redundant metals required by the metal layer in the chip, includes:
step S1021: the relative area of adjacent redundant metals is determined according to a preset formula, wherein the preset formula is:

$$C = \frac{{ε}_{r} S}{4 π kd} \qquad ( 1 )$$

in the formula, C denotes the capacitance value, εᵣ denotes a relative dielectric constant, d denotes the distance between the adjacent redundant metals, k denotes a static power constant, and S denotes the relative area of the adjacent redundant metals.

In order to avoid problems in the production process, the distance between the adjacent redundant metals is set according to a minimum spacing in design rules.

Step S1022: the length value is determined according to the relative area and the thickness of the redundant metals.

The formula for determining the length value is:

$$S = L \times d \qquad ( 2 )$$

in the formula, S denotes the relative area of the adjacent redundant metals, d denotes the thickness of the redundant metals, and L denotes the length value of the redundant metals.

Step S103: the redundant metals having a total length of the length value are inserted into a preset region of the metal layer, and are connected to a power source and a grounding power source, wherein the redundant metals connected to the power source and the redundant metals connected to the grounding power source are arranged in an interdigital form.

In order to avoid the problems in the production process, the width of the redundant metals is set according to the design rules of the metals in the current layer.

The redundant metals having the total length of the length value are divided into a plurality of segments of redundant metals, the number of division is not limited in the present application and is determined according to the situation. A part of the divided redundant metals is connected to the power source, and the other part of the divided redundant metals is connected to the grounding power source, the structural schematic diagram of connecting redundant metals 3 to a power source 2 and a grounding power source 1 in the interdigital form is shown in FIG. 2, and two adjacent redundant metals 3 form a capacitor, thereby increasing the contact area between the power grids, the capacitors between the power source 2 and the grounding power source 1 are increased, and since the capacitors can be used for storing electricity, a voltage stabilizing effect is also achieved.

Since the chip has a very high requirement for the area of the chip in the design, there is generally little space waste in the chip, and in the present application, the redundant metals are disposed in the interdigital form, on one hand, the occupied area of the chip can be reduced, and on the other hand, the capacitors increased per unit area can also be increased.

In the present embodiment, when the redundant metals are inserted, the redundant metals are connected to the power source and the grounding power source, that is, the redundant metals are grounded, and the potentials of the redundant metals are fixed, therefore a traditional parasitic parameter extraction tool and a simulation tool can quickly extract the parasitic parameters of the grounded redundant metals, and can also shield crosstalk between signal lines to obtain a relatively ideal time sequence; and since the redundant metals are grounded, the coupling between two metal wires can also be shielded. In the prior art, when the redundant metals are filled, a floating filling mode is used for filling, the redundant metals are not connected to fixed potentials, thereby exacerbating the crosstalk, and thus leading to a signal integrity problem. In addition, according to the above description, in the prior art, when the redundant metals are inserted, the redundant metals can only play a role in balancing the metal density, but in the present application, the redundant metals are doped and the redundant metals are connected to the power source and the grounding power source, thereby not only having the effect of balancing the metal density, but also having the effect of increasing the capacitors, stabilizing the voltage and shielding the crosstalk between the signal lines.

The chip includes a plurality of metal layers. It should be noted that the position where the redundant metals are inserted into the metal layer is not limited in the present application, and is determined according to the number of metal layers into which the redundant metals may be inserted.

When there are a plurality of metal layers into which the redundant metals may be inserted, there may be the following several situations: first, the redundant metals are inserted into the metal layer at the topmost layer, so that the number of through holes can be reduced, and the transient voltage reduction is reduced, and because the resistance of the through hole is relatively large in general, so the voltage drop loss is too large. Second, the redundant metals are inserted into the plurality of metal layers, and the redundant metals are sequentially inserted into the metal layers downwards from the metal layer at the topmost layer. This case is mainly involved when the redundant metals cannot be completely inserted into the metal layer at the topmost layer. Third, the metal layer into which the redundant metals are inserted is a layer with a minimum density of metal wires, since the metal layer with the minimum density of metal wires has a relatively serious transient voltage, the redundant metals are inserted into the layer with the minimum density of metal wires to realize voltage stabilization.

When there is only one metal layer into which the redundant metals may be inserted, the redundant metals are directly inserted into the metal layer.

In the present application, when the capacitors of the chip are increased, the capacitance value needing to be increased in the chip is determined, the length value of redundant metals to be inserted is determined according to the capacitance value, then the redundant metals are inserted into the preset region of the metal layer of the chip, and the redundant metals are connected to the power source and the grounding power source. The redundant metals increase the capacitors between the power source and the grounding power source, that is, increase the capacitors of the chip; moreover, no photomask needs to be used, so that the cost is reduced, and the manufacturing process of the chip is simplified; meanwhile, since the capacitors can be used for storing electricity, a voltage stabilizing effect is also achieved; and in addition, the redundant metals are arranged in the interdigital form in the present application, so that the occupied area can be reduced, the area is efficiently utilized, and the capacitors increased per unit area are increased at the same time.

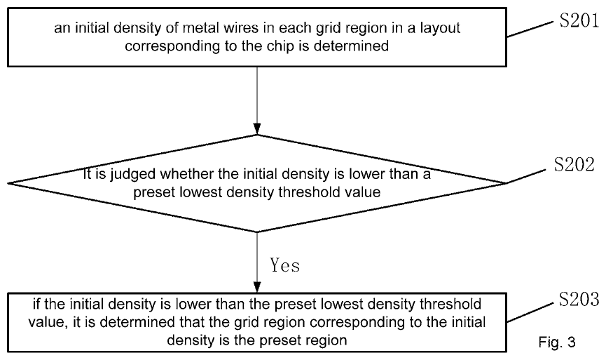

In one embodiment of the present application, with reference to FIG. 3, the determination process of the preset region includes:
step S201: an initial density of metal wires in each grid region in a layout corresponding to the chip is determined.

The filling of the redundant metals is generally completed in a wafer manufacturing plant and is located in the last stage of physical design of the layout, the time sequence and layout versus schematics (LVS), design rule check (DRC) and the like have been passed, and the design of the layout has been basically determined.

An EDA (Electronics Design Automation) tool divides the layout into several grid regions, and calculates the density of the metal wires in each grid region, which specifically refers to dividing the occupied area of signal lines and power lines on the current metal layer by the area of the current metal layer, the width of each layer of metal lines is determined by the process, and the EDA tool may give the number and length, so as to determine the area of the metal lines.

Step S202: it is judged whether the initial density is lower than a preset lowest density threshold value.

In the present application, the preset lowest density threshold value is not limited and may be set voluntarily.

Step S203: if the initial density is lower than the preset lowest density threshold value, it is determined that the grid region corresponding to the initial density is the preset region.

When the initial density of the metal wires in the grid region is lower than the preset lowest density threshold value, the region must be filled with the redundant metals, when the initial density is not lower than the preset lowest density threshold value, the region may be not filled with the redundant metals, or whether the region is filled with the redundant metals is judged according to the density of the metal wires in surrounding grid regions.

In one embodiment of the present application, when the initial density is not lower than the preset lowest density threshold value and is lower than a preset highest density threshold value, the method includes:
a density difference between the grid region and an adjacent grid region is determined;
it is judged whether the density difference exceeds a preset difference threshold value; and
if the density difference exceeds the preset difference threshold value, it is determined that the grid region is the preset region.

In the present application, the preset highest density threshold value is not limited and may be set voluntarily. Similarly, in the present application, the preset difference threshold value is not limited and may be set voluntarily, for example, the preset difference threshold value may be 5%, 7%, etc.

It can be understood that, when the density difference does not exceed the preset difference threshold value, there is no need to fill the redundant metals in the grid region.

Further, after the step of inserting the redundant metals having the total length of the length value into the preset region of the metal layer, and connecting the redundant metals to the power source and the grounding power source, the method further includes:
the density of the grid region is determined after the redundant metals are inserted, the density is used as a new initial density, and the step of judging whether the initial density is lower than the preset lowest density threshold value is executed, until the density difference between each grid region and the adjacent grid region does not exceed the preset difference threshold value.

The method for increasing the capacitors in the chip in the present application is described below in a specific embodiment.
Step 1: an initial density of metal wires in each grid region in a layout corresponding to the chip is determined;
step 2: it is judged whether the initial density is lower than a preset lowest density threshold value;
step 3: if the initial density does not exceed the preset lowest density threshold value, it is determined that the grid region corresponding to the initial density is a preset region;
step 4: if the initial density exceeds the preset lowest density threshold value and does not exceed a preset highest density threshold value, a density difference between the grid region and an adjacent grid region is determined;
step 5: it is judged whether the density difference exceeds a preset difference threshold value;
step 6: if the density difference exceeds the preset difference threshold value, it is determined that the grid region is the preset region;
step 7: a capacitance value needing to be increased in the chip is determined;
step 8: according to the capacitance value, a length value of redundant metals required by a metal layer in the chip is determined;
step 9: the redundant metals having a total length of the length value are inserted into the preset region of the metal layer, and are connected to a power source and a grounding power source, wherein the redundant metals connected to the power source and the redundant metals connected to the grounding power source are arranged in an interdigital form; and
step 10: the density of the grid region is determined after the redundant metals are inserted, the density is used as a new initial density, and the step 2 is executed until the density difference between each grid region and the adjacent grid region does not exceed the preset difference threshold value.

The present application further provides a chip, wherein redundant metals on the chip are connected to a power source and a grounding power source according to any method for increasing the capacitors in the chip as described above, and are arranged in an interdigital form.

In the present embodiment, by means of disposing the redundant metals on the metal layer of the chip in the interdigital form, not only can the density of the metal wires in different regions be balanced, but the capacitors of the chip can also be increased, and the voltage can be stabilized; moreover, no photomask needs to be used, so that the cost is reduced, and the manufacturing process of the chip is simplified; and in addition, the redundant metals are arranged in the interdigital form, so that the occupied area can be reduced, the area is efficiently utilized, and the capacitors increased per unit area are increased at the same time.

On the basis of the above embodiments, in one embodiment of the present application, a substrate material of the chip is a composite material of silicon dioxide and aluminum nitride, or a composite material of silicon dioxide and silicon nitride, or silicon dioxide doped with high-valence cations.

In the prior art, the substrate material of the chip is silicon dioxide, and in the present embodiment, the substrate material is the composite material of silicon dioxide and aluminum nitride (AlN) or silicon nitride (Si₃N₄), so that the dielectric constant can be increased, and then the capacitors are increased; or, the high-valence cations is doped, such as Nb⁵⁺ or the like, the high-valence cations replace Si to increase the dielectric constant, thereby increasing the capacitors.

The present application further provides a semiconductor device, and the semiconductor device includes the chip according to any one of the above embodiments.

Various embodiments in the present specification are described in a progressive manner, each embodiment focuses on the difference from other embodiments, and the same or similar parts between the embodiments may refer to each other. For the apparatus disclosed in the embodiments, since the apparatus corresponds to the method disclosed in the embodiments, the description is relatively simple, and relevant parts may refer to the description of the method.

The method for filling redundant metals in the chip, the chip and the semiconductor device provided in the present application are described in detail above. Specific examples are used herein to describe the principles and embodiments of the present application, and the description of the above embodiments is merely used to help understand the method of the present application and the core idea thereof. It should be noted that, for those ordinary skilled in the art, several improvements and modifications may be made to the present application without departing from the principle of the present application, and these improvements and modifications also fall within the protection scope of the claims of the present application.

1. A method for increasing capacitors in a chip, comprising:
determining a capacitance value needing to be increased in the chip;
according to the capacitance value, determining a length value of redundant metals required by a metal layer in the chip; and
inserting the redundant metals having a total length of the length value into a preset region of the metal layer, and connecting the redundant metals to a power source and a grounding power source, wherein the redundant metals connected to the power source and the redundant metals connected to the grounding power source are arranged in an interdigital form.

2. The method for increasing the capacitors in the chip according to claim 1, wherein when there are a plurality of metal layers into which the redundant metals may be inserted, the redundant metals are inserted into the metal layer at a topmost layer of the plurality of metal layers.

3. The method for increasing the capacitors in the chip according to claim 2, wherein the redundant metals are inserted into the metal layer at the topmost layer, so as to reduce the number of through holes and to reduce transient voltage reduction.

4. The method for increasing the capacitors in the chip according to claim 1, wherein when there are a plurality of metal layers into which the redundant metals may be inserted, the redundant metals are inserted into the plurality of metal layers, and the redundant metals are sequentially inserted into the metal layers downwards from the metal layer at a topmost layer of the plurality of metal layers.

5. The method for increasing the capacitors in the chip according to claim 4, wherein in the case that the redundant metals cannot be completely inserted into the metal layer at the topmost layer, the redundant metals are inserted into the plurality of metal layers, and the redundant metals are sequentially inserted into the metal layers downwards from the metal layer at the topmost layer.

6. The method for increasing the capacitors in the chip according to claim 1, wherein when there are a plurality of metal layers into which the redundant metals may be inserted, the metal layer into which the redundant metals are inserted is a layer with a minimum density of metal wires.

7. The method for increasing the capacitors in the chip according to claim 1, wherein determining the capacitance value needing to be increased in the chip comprises:
determining the capacitance value according to a width value, a spacing and a thickness value of the metal layer, as well as a dielectric constant of a dielectric layer in the chip.

8. The method for increasing the capacitors in the chip according to claim 1, wherein, according to the capacitance value, determining the length value of redundant metals required by the metal layer in the chip, comprises:
determining a relative area of adjacent redundant metals according to a preset formula, wherein the preset formula is:
$$C = \frac{{ε}_{r} S}{4 π kd}$$
in the formula, C denotes the capacitance value, εᵣ denotes a relative dielectric constant, d denotes a distance between the adjacent redundant metals, k denotes a static power constant, and S denotes the relative area of the adjacent redundant metals; and
determining the length value according to the relative area and a thickness of the redundant metals.

9. The method for increasing the capacitors in the chip according to claim 8, wherein a formula for determining the length value is:
$$S = L \times d$$
in the formula, S denotes the relative area of the adjacent redundant metals, d denotes the thickness of the redundant metals, and L denotes the length value of the redundant metals.

10. The method for increasing the capacitors in the chip according to claim 1, wherein when inserted into the metal layer, the redundant metals having the total length of the length value are divided into a plurality of segments of the redundant metals, a part of divided redundant metals is connected to the power source, and the other part of the divided redundant metals is connected to the grounding power source.

11. The method for increasing the capacitors in the chip according to claim 10, wherein the part of the divided redundant metals connected to the power source and the other part of the divided redundant metals connected to the grounding power source are distributed alternately.

12. The method for increasing the capacitors in the chip according to claim 10, wherein the part of the divided redundant metals connected to the power source and the other part of the divided redundant metals connected to the grounding power source are distributed in parallel.

13. The method for increasing the capacitors in the chip according to claim 1, wherein the determination process of the preset region comprises:
determining an initial density of metal wires in each grid region in a layout corresponding to the chip;
judging whether the initial density is lower than a preset lowest density threshold value; and
if the initial density is lower than the preset lowest density threshold value, determining that the grid region corresponding to the initial density is the preset region.

14. The method for increasing the capacitors in the chip according to claim 13, wherein when the initial density is not lower than the preset lowest density threshold value and is lower than a preset highest density threshold value, the method comprises:
determining a density difference between the grid region and an adjacent grid region;
judging whether the density difference exceeds a preset difference threshold value; and
if the density difference exceeds the preset difference threshold value, determining that the grid region is the preset region.

15. The method for increasing the capacitors in the chip according to claim 14, wherein when the density difference does not exceed the preset difference threshold value, the redundant metals are not filled in the grid region.

16. The method for increasing the capacitors in the chip according to claim 14, wherein after the step of inserting the redundant metals having the total length of the length value into the preset region of the metal layer, and connecting the redundant metals to the power source and the grounding power source, the method further comprises:
determining a density of the grid region after the redundant metals are inserted, using the density as a new initial density, and executing the step of judging whether the initial density is lower than the preset lowest density threshold value, until the density difference between the each grid region and the adjacent grid region does not exceed the preset difference threshold value.

17. The method for increasing the capacitors in the chip according to claim 13, wherein determining the initial density of metal wires in the each grid region in the layout corresponding to the chip comprises:
dividing the layout into several grid regions by means of an EDA tool, and calculating the density of the metal wires in the each grid region.

18. A chip, wherein redundant metals on the chip are connected to a power source and a grounding power source according to the method for increasing the capacitors in the chip according to claim 1, and are arranged in an interdigital form.

19. The chip according to claim 18, wherein a substrate material of the chip is a composite material of silicon dioxide and aluminum nitride, or a composite material of silicon dioxide and silicon nitride, or silicon dioxide doped with high-valence cations.

20. A semiconductor device, wherein the semiconductor device comprises the chip according to claim 18.
